(19) United States
(12) Patent Application Publication
(10) Pub. No.: US 2020/0127061 A1
(43) Pub. Date: Apr. 23, 2020

(54) DISPLAY PANEL

(71) Applicant: Wuhan China Star Optoelectronics Semiconductor Display Technology Co., Ltd., Wuhan, Hubei (CN)

(72) Inventor: Xin ZOU, Wuhan, Hubei (CN)

(73) Assignee: Wuhan China Star Optoelectronics Semiconductor Display Technology Co., Ltd., Wuhan, Hubei (CN)

(21) Appl. No.: 16/317,827

(22) PCT Filed: Aug. 2, 2018
(86) PCT No.: PCT/CN2018/098313

§ 371 Date: Jan. 15, 2019

(30) Foreign Application Priority Data
Jun. 5, 2018 (CN) 201810566833.2

(51) Int. Cl. H01L 27/32

(52) U.S. Cl. CPC H01L 27/3218; H01L 27/326

(57) ABSTRACT

A display panel is provided and has a transparent substrate having a conventional display area and a transparent display area; a plurality of first pixel units distributed in the conventional display area; and a plurality of second pixel units distributed in the transparent display area. Each of the first pixel units has a first light emitting area and a non-light emitting area, and each of the second pixel units has a second light emitting area and a transparent area, where a ratio of the first light emitting area in the first pixel unit is greater than a ratio of the second light emitting area in the second pixel unit.

### FIELD OF DISCLOSURE

The present disclosure relates to a field of liquid crystals, and more particularly to a display panel.

### BACKGROUND OF DISCLOSURE

Since birth of organic light-emitting display technology, it has gradually replaced liquid crystal displays due to its advantages of wide viewing angles, high contrast, wide color gamut, and fast response times. In recent years, pursuit of high-screen ratio in the display field has never stopped. After ultra-narrow bezels, full screen display is rising rapidly.

As far as the display of the mobile phone is concerned, due to breakthrough of flexible display technology, the display screen in a long side direction has been displayed without borders. However, there is a non-display area for the camera in an up and down direction due to disposing of a front camera. Therefore, an overall screen ratio cannot continue to increase.

Therefore, the conventional technology has drawbacks and there is an urgent need for improvement.

### Technical Problem

An object of embodiments of the present disclosure is to provide a display panel, which has a beneficial effect of improving overall screen ratio.

### Technical Solutions

An embodiment of the present disclosure provides a display panel, comprising:
a transparent substrate having a conventional display area and a transparent display area;
a plurality of first pixel units uniformly distributed in the conventional display area; and
a plurality of second pixel units uniformly distributed in the transparent display area;
wherein each of the first pixel units has a first light emitting area and a non-light emitting area, and each of the second pixel units has a second light emitting area and a transparent area, wherein a ratio of the first light emitting area in the first pixel unit is greater than a ratio of the second light emitting area in the second pixel unit; and
wherein the ratio of the first light emitting area in the first pixel unit ranges from 30% to 85%, and a size of each of the first pixel units is same as a size of each of the second pixel units.

In the display panel described by the present disclosure, the ratio of the second light emitting area in the second pixel unit ranges from 5% to 30%.

In the display panel described by the present disclosure, the first light emitting area of each of the first pixel units is provided with an organic light emitting layer, and the second light emitting area of each of the second pixel units is provided with an organic light emitting layer.

In the display panel described by the present disclosure, the transparent display area is disposed on a middle portion of the transparent substrate neighboring an upper edge of the transparent substrate, and the conventional display area is disposed around the transparent display area.

In the display panel described by the present disclosure, the transparent display area is round, rectangular, or rounded rectangle.

In the display panel described by the present disclosure, each of the second light emitting areas is provided with a red sub-pixel, a blue sub-pixel, and a green sub-pixel.

In the display panel described by the present disclosure, each of the second light emitting areas is provided with a sub-pixel, wherein the sub-pixel is a red sub-pixel, a blue sub-pixel, or a green sub-pixel.

In the display panel described by the present disclosure, each of the second light emitting area comprises a plurality of second light emitting sub-areas distributed at intervals, and each of the second light emitting sub-areas is provided with a sub-pixel, wherein the sub-pixel is a red sub-pixel, a blue sub-pixel, or a green sub-pixel.

An embodiment of the present disclosure further provides a display panel, comprising:
a transparent substrate having a conventional display area and a transparent display area;
a plurality of first pixel units uniformly distributed in the conventional display area; and
a plurality of second pixel units uniformly distributed in the transparent display area;
wherein each of the first pixel units has a first light emitting area and a non-light emitting area, and each of the second pixel units has a second light emitting area and a transparent area, wherein a ratio of the first light emitting area in the first pixel unit is greater than a ratio of the second light emitting area in the second pixel unit.

In the display panel described by the present disclosure, the ratio of the first light emitting area in the first pixel unit ranges from 30% to 85%.

In the display panel described by the present disclosure, the ratio of the second light emitting area in the second pixel unit ranges from 5% to 30%.

In the display panel described by the present disclosure, the first light emitting area of each of the first pixel units is provided with an organic light emitting layer, and the second light emitting area of each of the second pixel units is provided with an organic light emitting layer.

In the display panel described by the present disclosure, the transparent display area is disposed on a middle portion of the transparent substrate neighboring an upper edge of the transparent substrate, and the conventional display area is disposed around the transparent display area.

In the display panel described by the present disclosure, the transparent display area is round, rectangular, or rounded rectangle.

In the display panel described by the present disclosure, a size of each of the first pixel units is same as a size of each of the second pixel units.

In the display panel described by the present disclosure, each of the second light emitting areas is provided with a red sub-pixel, a blue sub-pixel, and a green sub-pixel.

In the display panel described by the present disclosure, each of the second light emitting areas is provided with a sub-pixel, wherein the sub-pixel is a red sub-pixel, a blue sub-pixel, or a green sub-pixel.

In the display panel described by the present disclosure, each of the second light emitting area comprises a plurality of second light emitting sub-areas distributed at intervals, and each of the second light emitting sub-areas is provided with a sub-pixel, wherein the sub-pixel is a red sub-pixel, a blue sub-pixel, or a green sub-pixel.

### Beneficial Effect

The present disclosure has a beneficial effect of improving an overall screen ratio by disposing a transparent display area on a display panel, where the area can be used to display and also can be used by cameras or optical sensors to collect light without the need to set another non-display area.

### DESCRIPTION OF DRAWINGS

In order to more clearly describe embodiments of the present disclosure or technical solutions in a conventional technology, drawings required to be used for the embodiments or descriptions of the conventional technology are simply described hereinafter. Apparently, the drawings described below only illustrate some embodiments of the present disclosure. Those skilled in the art can obtain other drawings based on these drawings disclosed herein without creative effort.

FIG. 1a is a first structural schematic diagram of a display panel in some embodiments of the present disclosure.

FIG. 1b is a second structural schematic diagram of a display panel in some embodiments of the present disclosure.

FIG. 2a is a third structural schematic diagram of a display panel in some embodiments of the present disclosure.

FIG. 2b is a fourth structural schematic diagram of a display panel in some embodiments of the present disclosure.

### BEST EMBODIMENTS OF PRESENT DISCLOSURE

Embodiments of the present disclosure are described in detail below, and examples of the embodiments are illustrated in drawings, wherein from beginning to end, same or similar reference numerals indicate same or similar elements or elements having the same or similar functions. The embodiments described below with reference to the drawings are merely intended to be illustrative of the disclosure and are not to be construed as limiting.

In the description of the present disclosure, it is to be understood that orientation or positional relationships of the terms of “center”, “longitudinal”, “transverse”, “length”, “width”, “thickness”, “upper”, “lower”, “front”, “back”, “left”, “right”, “vertical”, “horizontal”, “top”, “bottom”, “inside”, “outside”, “clockwise”, “counterclockwise”, etc. are based on orientation or positional relationships shown by the figures. It is merely for the convenience of describing the present disclosure and simplifying the description, but not indicating or implying, to which a device or a component is referred, must have a specific orientation, or must be constructed and operated in a specific orientation. Therefore, it should not be construed as limiting the disclosure. Moreover, the terms “first” and “second” are merely used for descriptive purposes and are not to be construed as indicating or implying a relative importance, or as implicitly indicating the number of the indicated technical features. Thus, features defining “first” or “second” may include one or more of the described features either explicitly or implicitly. In the description of the present disclosure, the meaning of “a plurality” is two or more unless otherwise specifically defined.

In the description of the present disclosure, it should be noted that the terms of “mount”, “connect with each other”, and “connect” are to be understood broadly. For example, it can be a fixed connection, a detachable connection, or an integral connection. It can be a mechanical connection, or it can be electrically connected or can be communicated with each other. It can be directly connected, or can be indirectly connected through an intermediate medium. It can mean two components connected to each other internally, or an interacting relationship between two components. The specific meanings of the above terms in the present disclosure can be understood by those skilled in the art in specific conditions.

In the present disclosure, a first feature “on” or “under” a second feature can include direct contact of the first and second features, and can also include that the first and second features are not in direct contact but are contacted by additional features between them. Moreover, the meaning of the first feature being “on”, “above” and “upside” the second feature includes the first feature directly above and obliquely above the second feature, or merely indicates that a horizontal height of the first feature is higher than a horizontal height of the second feature. The meaning of the first feature being “lower”, “below” and “downside” the second feature includes the first feature directly lower and below the second feature, or merely indicates that a horizontal height of the first feature is less than a horizontal height of the second feature.

The following publication provides many different embodiments or examples for implementing different structures of the present disclosure. In order to simplify the publication of the present disclosure, the components and arrangements of the specific examples are described below. Of course, they are merely examples and are not intended to limit the disclosure. In addition, the present disclosure may be repeated with reference to the numerals and/or reference numerals in the various examples, which are for the purpose of simplicity and clarity, and do not indicate the relationship between the various embodiments and/or arrangements discussed. Moreover, the present disclosure provides examples of various specific processes and materials, but one of ordinary skilled in the art will recognize the use of other processes and/or the use of other materials.

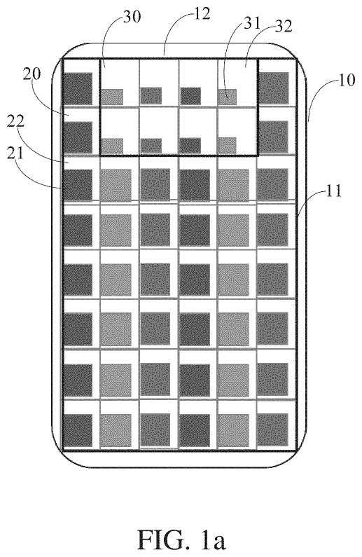

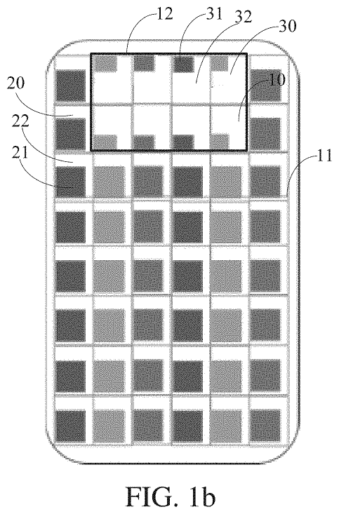

Refer to FIG. 1a, which is a structural diagram of a display panel of the present disclosure. The display panel includes a transparent substrate 10, and a plurality of first pixel units 20 and a plurality of second pixel units disposed on the transparent substrate 10. A size of each of the first pixel units 20 is same as a size of each of the second pixel units 30.

It can be understood that the transparent substrate 10 is further provided with a TFT device layer, an anode layer, a cathode layer and the like. The TFT device layer is disposed on the transparent substrate 10, the anode layer is disposed on the TFT device layer, the plurality of first pixel units 20 and the plurality of second pixel units 30 are disposed on the anode layer, and the cathode layer is disposed above the plurality of first pixel units 20 and the plurality of second pixel units 30. Of course, an insulating layer is also disposed between two adjacent metal layers, which is not described in detail herein.

The transparent substrate 10 has a conventional display area 11 and a transparent display area 12. The conventional display area 11 is mainly used to display. The transparent display area 12 is mainly used to display and used by cameras or optical sensors below the transparent display area 12 to collect light. The transparent display area 12 is substantially rectangular, rounded rectangle, or round. The transparent display area 12 is disposed on the transparent substrate 10 neighboring an upper edge of the transparent substrate 10. Of course, it can be understood that in some embodiments, the transparent display area 12 can also be disposed in other areas of the transparent substrate 10, such as a middle portion, a bottom portion, an upper left corner region, an upper right corner region, and the like.

In some embodiments, a touch layer is disposed on the plurality of first pixel units 20, but no touch layer is disposed on the plurality of second pixel units. For example, a transparent protective layer is disposed on the plurality of first pixel units 20 and the plurality of second pixel units 30. The transparent protective layer is provided with a first area corresponding to the conventional display area 11 and a second area corresponding to the transparent display area. The first area is provided with a touch circuit, but the second area is provided with no touch circuit.

The plurality of first pixel units 20 are distributed in an array in the conventional display area 11. Each of the first pixel units 20 has a first light emitting area 21 and a non-light emitting area 22. The first light emitting area 21 is provided with a single color organic light emitting layer. The organic light emitting layer provided in the first light emitting area 21 of the plurality of first pixel units 20 has three colors, which are red, green, and blue. That is to say, the organic light emitting layer in the first light-emitting area 21 corresponds to a red sub-pixel, a green sub-pixel, or a blue sub-pixel. A ratio of the first light emitting area 21 in the first pixel unit 20 ranges from 30% to 85%. In the present embodiment, the ratio is 85%. The organic light emitting layer is formed with an OLED light emitting element.

The plurality of second pixel units 30 are distributed in an array in the transparent display area 12. Each of the second pixel units has a second light emitting area 31 and a transparent area 32, where a ratio of the first light emitting area 21 in the first pixel unit 20 is greater than a ratio of the second light emitting area 31 in the second pixel unit 30. The ratio of the second light emitting area 31 in the second pixel unit 30 ranges from 5% to 30%. In the present embodiment, the ratio is 25%. In the embodiment, the positions of the second light-emitting areas 31 of the second pixel units 30 are corresponding and same as each other. The second light emitting areas 31 are all located at a lower left corner, a lower right corner, an upper left corner, or an upper right corner of an area of the second pixel units 30.

The second light emitting area 31 is provided with a single color organic light emitting layer. The organic light emitting layer provided in the second light emitting area 31 of the plurality of second pixel units 30 has three colors, which are red, green, and blue. That is to say, the organic light emitting layer in the first light-emitting area 31 corresponds to a red sub-pixel, a green sub-pixel, or a blue sub-pixel. The organic light emitting layer is formed with an OLED light emitting element.

The present disclosure has a beneficial effect of improving an overall screen ratio by disposing a transparent display area on a display panel, where the area can be used to display and also can be used by cameras or optical sensors to collect light without the need to set another non-display area.

Referring to FIG. 1b, it can be understood that in some embodiments, there are two rows of second pixel units 30. In a first row of the second pixel unit 30, the second light emitting areas 31 are all located above an area of the second pixel unit 30 at where the second light emitting areas 31 are located, for example, upper left or upper right. In a second row of the second pixel unit 30, the second light emitting areas 31 are all located below an area of the second pixel unit 30 at where the second light emitting areas 31 are located, for example, lower left or lower right. This allows a sensor with a relatively large area to be placed under the transparent display area.

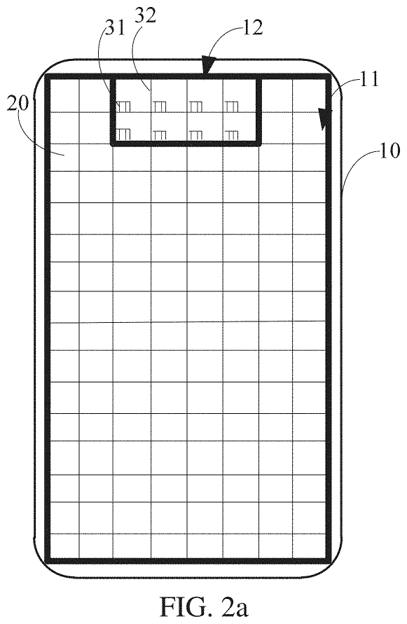

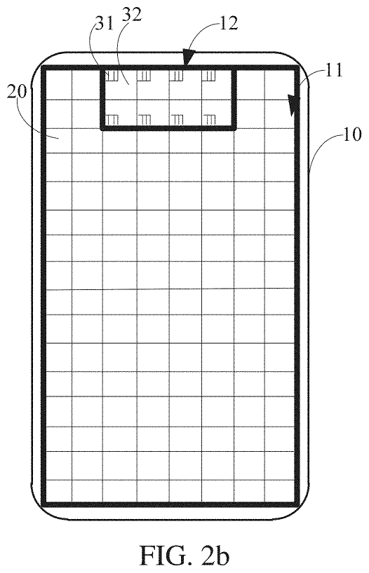

Refer to FIG. 2a, which is another structural diagram of a display panel of the present disclosure. The display panel includes a transparent substrate 10, and a plurality of first pixel units 20 and a plurality of second pixel units disposed on the transparent substrate 10. A size of each of the first pixel units 20 is same as a size of each of the second pixel units 30.

It can be understood that the transparent substrate 10 is further provided with a TFT device layer, an anode layer, a cathode layer and the like. The TFT device layer is disposed on the transparent substrate 10, the anode layer is disposed on the TFT device layer, the plurality of first pixel units 20 and the plurality of second pixel units 30 are disposed on the anode layer, and the cathode layer is disposed above the plurality of first pixel units 20 and the plurality of second pixel units 30. Of course, an insulating layer is also disposed between two adjacent metal layers, which is not described in detail herein.

The transparent substrate 10 has a conventional display area 11 and a transparent display area 12. The conventional display area 11 is mainly used to display. The transparent display area 12 is mainly used to display and used by cameras or optical sensors below the transparent display area 12 to collect light. The transparent display area 12 is substantially rectangular, rounded rectangle, or round. The transparent display area 12 is disposed on the transparent substrate 10 neighboring an upper edge of the transparent substrate 10.

In some embodiments, a touch layer is disposed on the plurality of first pixel units 20, but no touch layer is disposed on the plurality of second pixel units. For example, a transparent protective layer is disposed on the plurality of first pixel units 20 and the plurality of second pixel units 30. The transparent protective layer is provided with a first area corresponding to the conventional display area 11 and a second area corresponding to the transparent display area. The first area is provided with a touch circuit, but the second area is provided with no touch circuit.

The plurality of first pixel units 20 are distributed in an array in the conventional display area 11. Each of the first pixel units 20 has a first light emitting area and a non-light emitting area. The first light emitting area 21 is provided with three single color organic light emitting layers, i.e., a red sub-pixel, a green sub-pixel, and a blue sub-pixel. The organic light emitting layer provided in the first light emitting area 21 of the plurality of first pixel units 20 has three colors, which are red, green, and blue. That is to say, the organic light emitting layer in the first light-emitting area corresponds to a red sub-pixel, a green sub-pixel, or a blue sub-pixel. A ratio of the first light emitting area in the first pixel unit 20 ranges from 30% to 85%. In the present embodiment, the ratio is 85%. The organic light emitting layer is formed with an OLED light emitting element.

The plurality of second pixel units 30 are distributed in an array in the transparent display area 12. Each of the second pixel units has a second light emitting area 31 and a transparent area 32, where a ratio of the first light emitting area 21 in the first pixel unit 20 is greater than a ratio of the second light emitting area 31 in the second pixel unit 30. The ratio of the second light emitting area 31 in the second pixel unit 30 ranges from 5% to 30%. In the present embodiment, the ratio is 25%. In the embodiment, the positions of the second light-emitting areas 31 of the second pixel units 30 are corresponding and same as each other. The second light emitting areas 31 are all located at a lower left corner, a lower right corner, an upper left corner, or an upper right corner of an area of the second pixel units 30.

The second light-emitting region 31 is an integral piece, and three single color organic light-emitting devices are disposed in the second light-emitting region 31, i.e., a red sub-pixel, a green sub-pixel, and a blue sub-pixel. The organic light emitting layer is formed with an OLED light emitting element.

It can be understood that in some embodiments, the second light emitting area 31 in the same second pixel unit 30 may include three second light emitting sub-areas distributed at intervals, and each of the second light emitting sub-areas corresponds to a single color organic light emitting device.

Referring to FIG. 2b, it can be understood that in some embodiments, there are two rows of second pixel units 30. In a first row of the second pixel unit 30, the second light emitting areas 31 are all located above an area of the second pixel unit 30 at where the second light emitting areas 31 are located, for example, upper left or upper right. In a second row of the second pixel unit 30, the second light emitting areas 31 are all located below an area of the second pixel unit 30 at where the second light emitting areas 31 are located, for example, lower left or lower right. This allows a sensor with a relatively large area to be placed under the transparent display area.

The present disclosure has a beneficial effect of improving an overall screen ratio by disposing a transparent display area on a display panel, where the area can be used to display and also can be used by cameras or optical sensors to collect light without the need to set another non-display area.

The display panel provided by embodiments of the present disclosure has been described in detail above, and the principles and embodiments of the present disclosure are described in detail herein. The description of the above embodiments is only for the purpose of understanding the present disclosure. At the same time, the specific embodiments and application ranges can be changed by those skilled in the art according to the idea of the present disclosure. In conclusion, the content of the specification should not be construed as limiting the disclosure.

What is claimed is:

1. A display panel, comprising:
a transparent substrate having a conventional display area and a transparent display area;
a plurality of first pixel units uniformly distributed in the conventional display area; and
a plurality of second pixel units uniformly distributed in the transparent display area;
wherein each of the first pixel units has a first light emitting area and a non-light emitting area, and each of the second pixel units has a second light emitting area and a transparent area, wherein a ratio of the first light emitting area in the first pixel unit is greater than a ratio of the second light emitting area in the second pixel unit; and
wherein the ratio of the first light emitting area in the first pixel unit ranges from 30% to 85%, and a size of each of the first pixel units is same as a size of each of the second pixel units.

2. The display panel according to claim 1, wherein the ratio of the second light emitting area in the second pixel unit ranges from 5% to 30%.

3. The display panel according to claim 1, wherein the first light emitting area of each of the first pixel units is provided with an organic light emitting layer, and the second light emitting area of each of the second pixel units is provided with an organic light emitting layer.

4. The display panel according to claim 1, wherein the transparent display area is disposed on a middle portion of the transparent substrate neighboring an upper edge of the transparent substrate, and the conventional display area is disposed around the transparent display area.

5. The display panel according to claim 4, wherein the transparent display area is round, rectangular, or is a rounded rectangle.

6. The display panel according to claim 1, wherein each of the second light emitting areas is provided with a red sub-pixel, a blue sub-pixel, and a green sub-pixel.

7. The display panel according to claim 1, wherein each of the second light emitting areas is provided with a sub-pixel, wherein the sub-pixel is a red sub-pixel, a blue sub-pixel, or a green sub-pixel.

8. The display panel according to claim 1, wherein each of the second light emitting area comprises a plurality of second light emitting sub-areas distributed at intervals, and each of the second light emitting sub-areas is provided with a sub-pixel, wherein the sub-pixel is a red sub-pixel, a blue sub-pixel, or a green sub-pixel.

9. A display panel, comprising:
a transparent substrate having a conventional display area and a transparent display area;
a plurality of first pixel units uniformly distributed in the conventional display area; and
a plurality of second pixel units uniformly distributed in the transparent display area;
wherein each of the first pixel units has a first light emitting area and a non-light emitting area, and each of the second pixel units has a second light emitting area and a transparent area, wherein a ratio of the first light emitting area in the first pixel unit is greater than a ratio of the second light emitting area in the second pixel unit.

10. The display panel according to claim 9, wherein the ratio of the first light emitting area in the first pixel unit ranges from 30% to 85%.

11. The display panel according to claim 10, wherein the ratio of the second light emitting area in the second pixel unit ranges from 5% to 30%.

12. The display panel according to claim 9, wherein the first light emitting area of each of the first pixel units is provided with an organic light emitting layer, and the second light emitting area of each of the second pixel units is provided with an organic light emitting layer.

13. The display panel according to claim 9, wherein the transparent display area is disposed on a middle portion of the transparent substrate neighboring an upper edge of the transparent substrate, and the conventional display area is disposed around the transparent display area.

14. The display panel according to claim 13, wherein the transparent display area is round, rectangular, or rounded rectangle.

15. The display panel according to claim 9, wherein a size of each of the first pixel units is same as a size of each of the second pixel units.

16. The display panel according to claim 9, wherein each of the second light emitting areas is provided with a red sub-pixel, a blue sub-pixel, and a green sub-pixel.

17. The display panel according to claim 9, wherein each of the second light emitting areas is provided with a sub-pixel, wherein the sub-pixel is a red sub-pixel, a blue sub-pixel, or a green sub-pixel.

18. The display panel according to claim 9, wherein each of the second light emitting area comprises a plurality of second light emitting sub-areas distributed at intervals, and each of the second light emitting sub-areas is provided with a sub-pixel, wherein the sub-pixel is a red sub-pixel, a blue sub-pixel, or a green sub-pixel.
